(19) United States
(12) Patent Application Publication
(10) Pub. No.: US 2025/0357257 A1
(43) Pub. Date: Nov. 20, 2025

(54) INTEGRATED CIRCUIT PACKAGES AND METHODS OF FORMING THE SAME

(71) Applicant: Taiwan Semiconductor Manufacturing Co., Ltd., Hsinchu (TW)

(72) Inventors: Chih-Chao Chou, Hsinchu (TW); Ching-Wei Tsai, Hsinchu (TW); Yi-Hsun Chiu, Zhubei City (TW)

(21) Appl. No.: 19/283,957

(22) Filed: Jul. 29, 2025

Related U.S. Application Data
(63) Continuation of application No. 18/584,080, filed on Feb. 22, 2024.
(60) Provisional application No. 63/603,888, filed on Nov. 29, 2023.

(51) Int. Cl. H01L 23/373; H01L 23/00; H01L 23/14; H01L 23/48; H01L 23/498; H01L 25/00; H01L 25/065; H01L 25/18

(52) U.S. Cl. CPC H01L 23/3738; H01L 23/14; H01L 23/481; H01L 23/49822; H01L 24/32; H01L 24/80; H01L 25/0657; H01L 25/18; H01L 25/50; H01L 2224/32145; H01L 2224/32225; H01L 2224/80896; H01L 2924/1611

(57) ABSTRACT

A device includes a semiconductor die bonded to an integrated circuit die, wherein the integrated circuit die includes a first interconnect structure that has a metal density of at least 50%, a first redistribution structure having a metal density of at least 50%, wherein the first interconnect structure is bonded to the first redistribution structure, and a composite heat dissipation material between a bottom surface of the first interconnect structure and a top surface of the first redistribution structure.

### PRIORITY CLAIM AND CROSS-REFERENCE

This application is a continuation of U.S. patent application Ser. No. 18/584,080, filed on Feb. 22, 2024, which claims the benefit of U.S. Provisional Application No. 63/603,888, filed on Nov. 29, 2023, each application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, and 7 illustrate cross-sectional views of intermediate steps during a process for forming an integrated circuit die, in accordance with some embodiments.

FIGS. 8 and 9 illustrate cross-sectional views of intermediate steps during a process for forming a package component, in accordance with some embodiments.

FIGS. 10, 11, 12, and 13 illustrate cross-sectional views of intermediate steps during a process for forming a package, in accordance with some embodiments.

FIGS. 14, 15, 16, and 17 illustrate cross-sectional views of intermediate steps during a process for forming a package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a package component is formed with a back-side interconnect structure having a high metal density. This can allow for improved heat dissipation within the package component. The package component may be attached to a redistribution structure to form a package. The redistribution structure may have a high metal density, which can improve heat dissipation of the package. An underfill having a high thermal conductivity may be deposited between the package component and the redistribution structure, which can facilitate heat transfer from the package component to the redistribution structure.

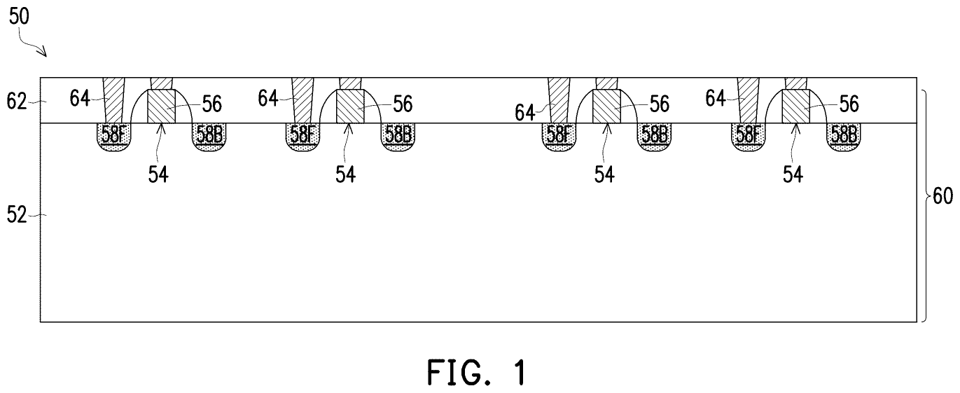

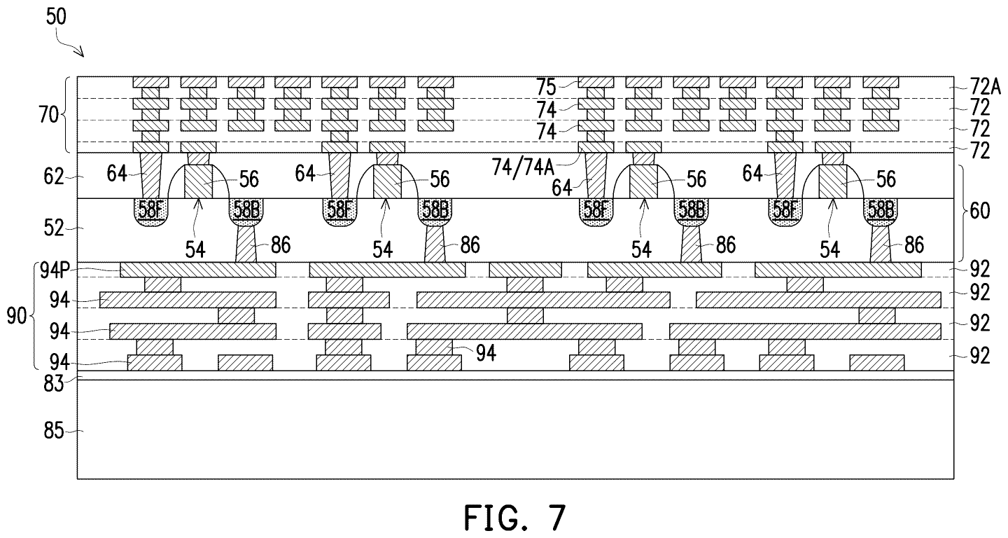

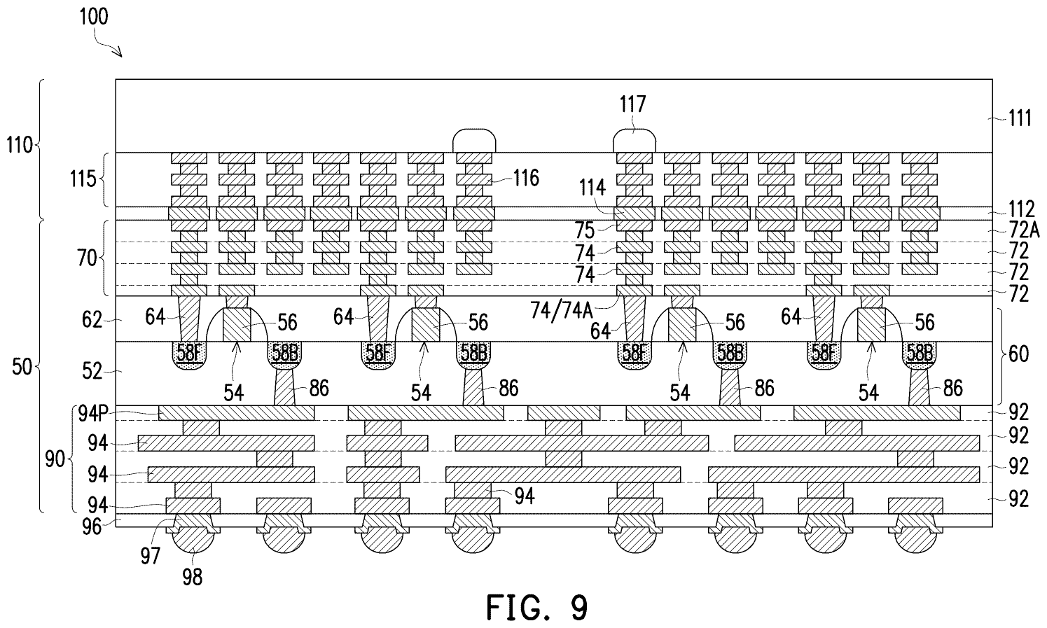

FIGS. 1-7 are cross-sectional views of intermediate steps during a process for forming an integrated circuit die 50 (see FIG. 7), in accordance with some embodiments. The integrated circuit die 50 will be packaged in subsequent processing to form a package component 100 (see FIG. 9). The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. The integrated circuit die 50 may be formed in a wafer, which includes different device regions that are singulated in subsequent steps to form a plurality of integrated circuit dies.

In FIG. 1, a semiconductor substrate 52 is provided, in accordance with some embodiments. The semiconductor substrate 52 may be silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back side.

Devices 54 (represented by a transistor) are formed at the front surface of the semiconductor substrate 52. The devices 54 may be active devices (e.g., transistors, diodes, etc.), capacitors, resistors, etc. The devices 54 may be formed in a front-end of line (FEOL) process by acceptable deposition, photolithography, and etching techniques. For example, the devices 54 may include gate structures 56 and source/drain regions 58, where the gate structures 56 are on channel regions, and the source/drain regions 58 are adjacent the channel regions. Source/drain region(s) 58 may refer to a source or a drain, individually or collectively dependent upon the context. Although the devices 54 are illustrated as planar transistors, they may also be nanostructure field-effect transistors (Nanostructure-FETs), fin field-effect transistors (FinFETs), or the like. The channel regions may be patterned regions of the semiconductor substrate 52. For example, the channel regions may be regions of semiconductor fins, semiconductor nanosheets, semiconductor nanowires, or the like that are patterned in the semiconductor substrate 52.

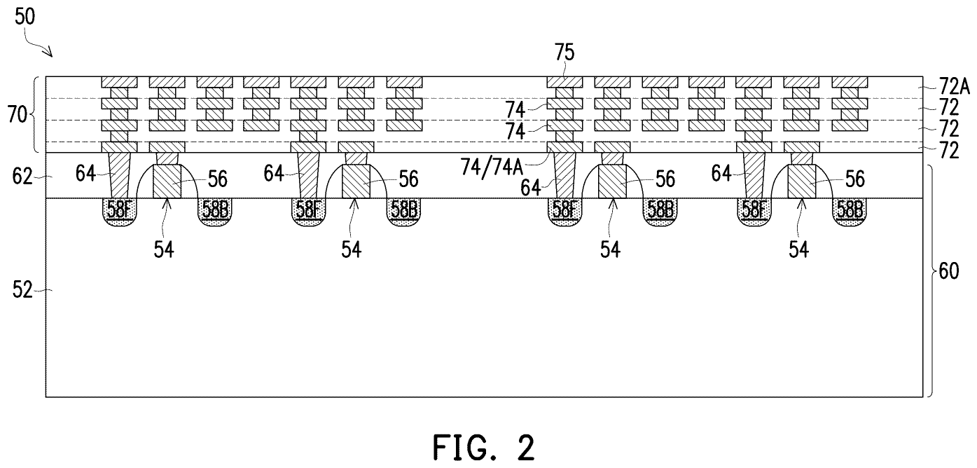

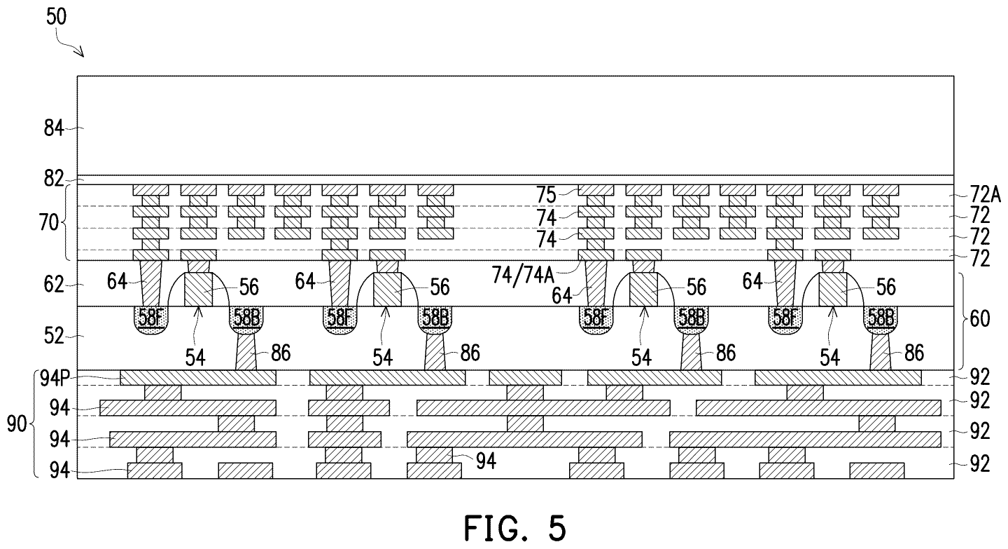

As subsequently described in greater detail, an upper interconnect structure (e.g., front-side interconnect structure 70 of FIG. 2) will be formed over the semiconductor substrate 52. Some or all of the semiconductor substrate 52 will then be removed and replaced with a lower interconnect structure (e.g., back-side interconnect structure 90 of FIG. 5). Thus, a device layer 60 of the devices 54 is formed between a front-side interconnect structure and a back-side interconnect structure. The front-side and back-side interconnect structures each include conductive features that are connected to the devices 54 of the device layer 60. The conductive features (e.g., interconnects) of the front-side interconnect structure will be connected to front-sides of the source/drain regions 58F and the gate structures 56 to form integrated circuits, such as logic circuits, memory circuits, image sensor circuits, or the like. The conductive features (e.g., interconnects) of the back-side interconnect structure will be connected to back-sides of the source/drain regions 58B to provide power, ground, and/or input/output connections for the integrated circuits.

An inter-layer dielectric (ILD) 62 is formed over the active surface of the semiconductor substrate 52. The inter-layer dielectric 62 surrounds and may cover the devices 54, e.g., the gate structures 56 and/or the source/drain regions 58. The inter-layer dielectric 62 may include one or more dielectric layers formed of dielectric materials such as Phospho-Silicate Glass (PSG), Boro-Silicate Glass (BSG), Boron-Doped Phospho-Silicate Glass (BPSG), undoped Silicate Glass (USG), or the like.

Upper contacts 64 are formed through the inter-layer dielectric 62 to physically and electrically couple the devices 54. For example, the upper contacts 64 may include gate contacts and source/drain contacts that are physically and electrically coupled to, respectively, the gate structures 56 and the source/drain regions 58F. Specifically, the upper contacts 64 are in contact with the front-sides of the source/drain regions 58F. The upper contacts 64 may be formed of a suitable conductive material such as tungsten, cobalt, nickel, copper, silver, gold, aluminum, the like, or combinations thereof, which may be formed by a deposition process such as physical vapor deposition (PVD) or chemical vapor deposition (CVD), a plating process such as electrolytic or electroless plating, or the like.

In FIG. 2, a front-side interconnect structure 70 is formed on the device layer 60, in accordance with some embodiments. The front-side interconnect structure 70 is formed at a front-side of the semiconductor substrate 52/the device layer 60 (e.g., over the inter-layer dielectric 62 of a side of the semiconductor substrate 52 on which the devices 54 are formed). The front-side interconnect structure 70 includes dielectric layers 72 and layers of conductive features 74 in the dielectric layers 72. The front-side interconnect structure 70 includes any desired number of layers of the conductive features 74. The conductive features 74 may include conductive lines, conductive vias, conductive pads, metallization patterns, redistribution layers, or the like. In some embodiments, the front-side interconnect structure 70 has a metal density of less than about 50%, though other metal densities are possible.

The dielectric layers 72 may be formed of a dielectric material. Acceptable dielectric materials include silicon oxide, phosphosilicate glass (PSG), borosilicate glass (BSG), boron-doped phosphosilicate glass (BPSG), or the like, which may be formed by CVD, atomic layer deposition (ALD), or the like. The dielectric layers 72 may be formed of a low-k dielectric material having a k-value lower than about 3.0. The dielectric layers 72 may be formed of an extra-low-k (ELK) dielectric material having a k-value lower than about 2.5. In some embodiments, the top-most dielectric layer 72A (e.g., the dielectric layer 72 at a top surface of the front-side interconnect structure 70) may be a material suitable for dielectric-to-dielectric bonding, such as silicon oxide, silicon oxynitride, or the like. Accordingly, the top-most dielectric layer 72A may also be referred to as the bonding layer 72A herein.

The conductive features 74 may include conductive lines and vias. The conductive vias may extend through respective ones of the dielectric layers 72 to provide vertical connections between layers of conductive lines. The conductive features 74 may be formed by a damascene process, such as a single damascene process, a dual damascene process, or the like. In a damascene process, a dielectric layer 72 is patterned utilizing photolithography and etching techniques to form interconnect openings (including trenches and via openings) corresponding to the desired pattern of the conductive features 74. The interconnect openings may then be filled with a conductive material. Suitable conductive materials include copper, silver, gold, tungsten, aluminum, combinations thereof, or the like, which may be formed by electroplating or the like. In some embodiments, bond pads 75 are formed at the top surface of the front-side interconnect structure 70, such as in the top-most dielectric layer 72A. The bond pads 75 may be considered part of the conductive features 74 and may be formed using similar techniques, in some cases. In some embodiments, the bond pads 75 comprise a material suitable for metal-to-metal bonding, such as copper or the like.

The conductive features 74 are connected to the devices 54 (e.g., the gate structures 56 and the source/drain regions 58F) by the upper contacts 64. Therefore, the conductive features 74 are interconnects that interconnect the devices 54 to form integrated circuits (previously described). The conductive features 74 are small so that a high density of integrated circuits may be formed.

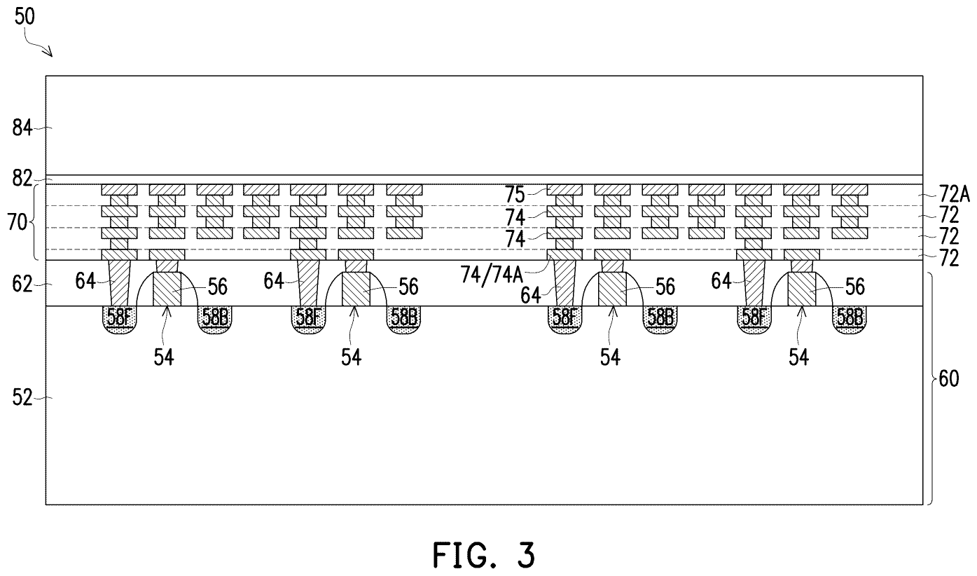

In FIG. 3, a first carrier substrate 84 is bonded to a top surface of the front-side interconnect structure 70, in accordance with some embodiments. The first carrier substrate 84 may be bonded to the front-side interconnect structure 70 by one or more bonding layer(s) 82. The first carrier substrate 84 may be a glass support substrate, a ceramic support substrate, a semiconductor substrate (e.g., a silicon substrate), a wafer (e.g., a silicon wafer), or the like. The first carrier substrate 84 may provide structural support during subsequent processing steps. The first carrier substrate 84 is substantially free of any active or passive devices.

In some embodiments, the first carrier substrate 84 may be bonded to the front-side interconnect structure 70 using a suitable technique such as dielectric-to-dielectric bonding, or the like. Dielectric-to-dielectric bonding may include depositing bonding layer(s) 82 on the front-side interconnect structure 70 and/or the first carrier substrate 84. In some embodiments, the bonding layer(s) 82 are formed of silicon oxide (e.g., a high density plasma (HDP) oxide or the like) that is deposited by CVD, ALD, or the like. The bonding layer(s) 82 may likewise include oxide layers that are formed prior to bonding using, for example, CVD, ALD, thermal oxidation, or the like. Other suitable materials may be used for the bonding layer(s) 82. In some embodiments, the bonding layer(s) 82 are not utilized and are omitted. In some embodiments, the bonding layer(s) 82 may comprise the bonding layer 72A of the front-side interconnect structure 70.

The dielectric-to-dielectric bonding process may further include performing a surface treatment on one or more of the bonding layer(s) 82. The surface treatment may include a plasma treatment. The plasma treatment may be performed in a vacuum environment. After the plasma treatment, the surface treatment may further include performing a cleaning process (e.g., a rinse with deionized water or the like) on one or more of the bonding layer(s) 82. The first carrier substrate 84 is then aligned with the front-side interconnect structure 70 and the two are pressed against each other to initiate a pre-bonding of the first carrier substrate 84 to the front-side interconnect structure 70. The pre-bonding may be performed at about room temperature. After the pre-bonding, an annealing process may be performed. The bonds are strengthened by the annealing process.

In other embodiments, the bonding layer 82 is a release layer or the like, and a dielectric-to-dielectric bonding process is not used. In such embodiments, the bonding layer 82 may be formed of a polymer-based material, which may be removed along with the first carrier substrate 84 from the front-side interconnect structure 70 in subsequent steps. In some embodiments, the bonding layer 82 is an epoxy-based thermal-release material, which loses its adhesive property when heated, such as a light-to-heat-conversion (LTHC) release coating. In some embodiments, the bonding layer 82 may comprise an ultra-violet (UV) glue, which loses its adhesive property when exposed to UV light. The bonding layer 82 may be dispensed as a liquid and cured, may be a laminate film laminated onto the first carrier substrate 84, or the like. The top surface of the bonding layer 82 may be leveled and may have a high degree of planarity.

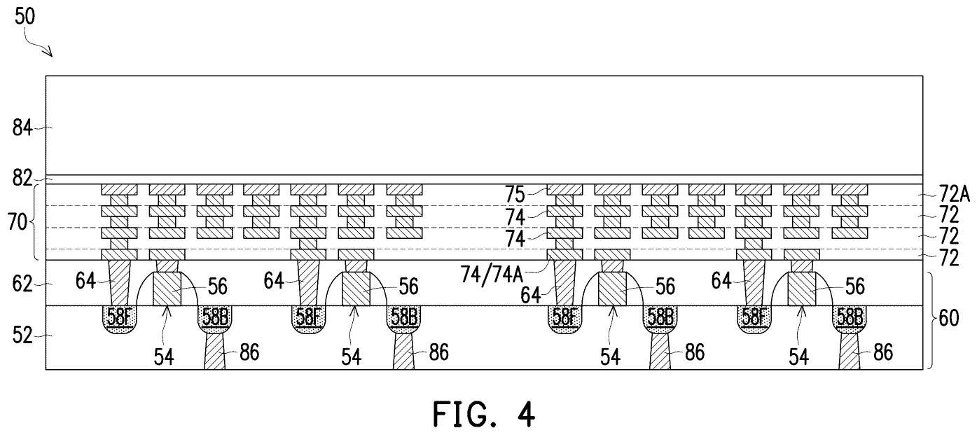

In FIG. 4, the semiconductor substrate 52 is thinned to reduce the thickness of the back-side portions of the semiconductor substrate 52. The back-side of the semiconductor substrate 52 refers to the side opposite to the front-side of the semiconductor substrate 52. The thinning process may include a mechanical grinding, a chemical mechanical polish (CMP), an etch back, a combination thereof, or the like.

Lower contacts 86 are formed through the semiconductor substrate 52 to electrically and physically couple the devices 54. Specifically, the lower contacts 86 are in contact with the back-sides of the source/drain regions 58B. As an example to form the lower contacts 86, contact openings may be formed through the semiconductor substrate 52 to expose the source/drain regions 58B. The contact openings may be formed using acceptable photolithography and etching techniques. A liner, such as a diffusion barrier layer, an adhesion layer, or the like, and a conductive material are then formed in the contact openings. The liner may include titanium, titanium nitride, tantalum, tantalum nitride, a combination thereof, or the like. The liner may be deposited by a conformal deposition process, such as physical vapor deposition (PVD), chemical vapor deposition (CVD), or the like. In some embodiments, the liner may include an adhesion layer and at least a portion of the adhesion layer may be treated to form a diffusion barrier layer. The conductive material may be tungsten, cobalt, ruthenium, aluminum, nickel, copper, a copper alloy, silver, gold, a combination thereof, or the like. The conductive material may be deposited by PVD, CVD, ALD, or the like. A planarization process, such as a CMP, may be performed to remove excess material from the back-side surface of the semiconductor substrate 52. The remaining liner and conductive material in the contact openings forms the lower contacts 86.

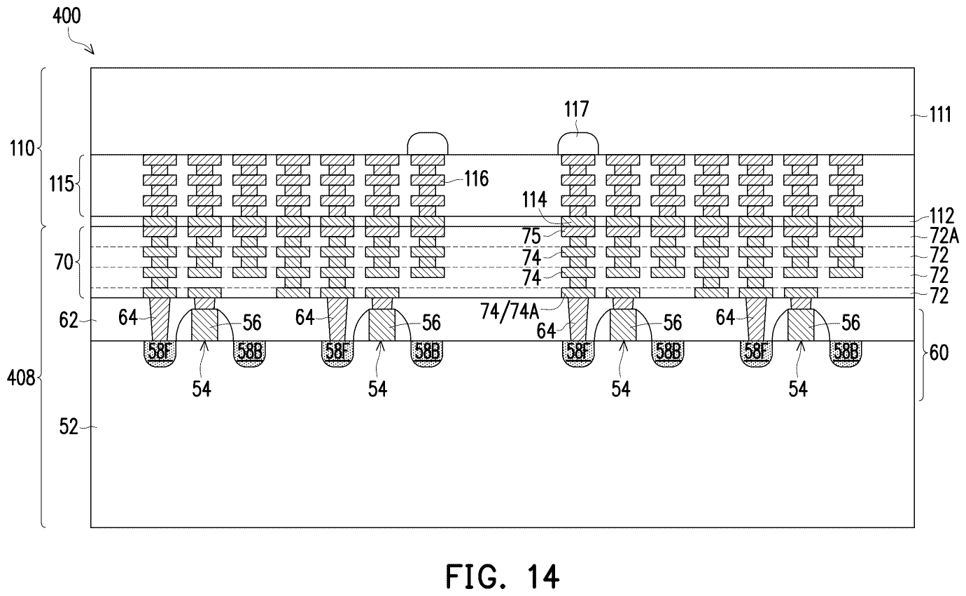

In FIG. 5, a back-side interconnect structure 90 is formed on the inactive surface of the semiconductor substrate 52, in accordance with some embodiments. The back-side interconnect structure 90 includes dielectric layers 92 and layers of conductive features 94 in the dielectric layers 92. The back-side interconnect structure 90 includes any desired number of layers of the conductive features 94. In this manner, an integrated circuit die 50 may be formed that comprises a front-side interconnect structure 70, a device layer 60, and a back-side interconnect structure 90. In another embodiment (subsequently described for FIGS. 14-17), the back-side interconnect structure 90 is omitted.

The dielectric layers 92 may be formed of a dielectric material. Acceptable dielectric materials include silicon oxide, phosphosilicate glass (PSG), borosilicate glass (BSG), boron-doped phosphosilicate glass (BPSG), or the like, which may be formed by CVD, ALD, or the like. The dielectric layers 92 may be formed of a low-k dielectric material having a k-value lower than about 3.0. The dielectric layers 92 may be formed of an extra-low-k (ELK) dielectric material having a k-value lower than about 2.5. Other materials are possible.

The conductive features 94 may include, for example, conductive lines, conductive vias, or the like. The conductive vias may extend through respective ones of the dielectric layers 92 to provide vertical connections between layers of conductive lines. The conductive features 94 may be formed by a damascene process, such as a single damascene process, a dual damascene process, or the like. In a damascene process, a dielectric layer 92 is patterned utilizing photolithography and etching techniques to form interconnect openings (including trenches and via openings) corresponding to the desired pattern of the conductive features 94. The interconnect openings may then be filled with a conductive material. Suitable conductive materials include copper, silver, gold, tungsten, aluminum, combinations thereof, or the like, which may be formed by electroplating or the like.

In some embodiments, the conductive features 94 form a power distribution network for the integrated circuit die 50. A power distribution network includes conductive lines (e.g., power rails) for providing reference and supply voltages to the devices 54 of the integrated circuit die 50. The conductive features 94 are large so that the power distribution networks may have a low resistance. The back-side interconnect structure 90 and the front-side interconnect structure 70 are formed in processes of different technology nodes. The technology node of the process for forming the back-side interconnect structure 90 is larger than the technology node of the process for forming the front-side interconnect structure 70. As such, the conductive features 94 have a larger minimum feature size than the conductive features 74.

In some embodiments, the conductive features 94 are large to facilitate heat transfer within the integrated circuit die 50. For example, larger conductive features 94 formed of metal may allow for the efficient transfer of heat away from the devices 54 and toward the back-side of the integrated circuit die 50. For example, in some embodiments, a thickness of a conductive line may be in the range of about 0.06 μm to about 0.36 μm, or a width of a conductive line may be in the range of about 0.12 μm to about 0.72 μm. A thickness or width of the conductive line of the conductive features 94 may be greater than that of the conductive features 74. Conductive lines or other conductive features 94 may have other dimensions in other embodiments.

In some embodiments, the overall metal density of the back-side interconnect structure 90 may be high (e.g., higher than the overall metal density of the front-side interconnect structure 70) in order improve thermal spreading. For example, in some embodiments, conductive features 94 may form about 50% to about 70% of the volume of the back-side interconnect structure 90. Other metal densities are possible. In some embodiments, some conductive features 94 may be dummy conductive features that facilitate heat transfer. By forming a back-side interconnect structure 90 having large and dense conductive features 94, heat may be more efficiently transferred within an integrated circuit die 50. This can improve the thermal properties, the efficiency, the reliability, and the operation of the integrated circuit die 50.

In some embodiments, some of the conductive features 94 are power rails 94P, which are conductive lines of the power distribution network (PDN). The power rails 94P are used to electrically couple some of the source/drain regions 58B to a reference voltage, supply voltage, or the like. For example, the power rails 94P are connected to some of the lower contacts 86, which are connected to some of the source/drain regions 58B. The back-side interconnect structure 90 may accommodate wider power rails than the front-side interconnect structure 70, reducing resistance and increasing efficiency of power delivery to the integrated circuit die 50. For example, in some embodiments, a width of a first level conductive line (e.g., power rail 94P) of the back-side interconnect structure 90 may be at least twice a width of a conductive line 74 of the front-side interconnect structure 70. More generally, the minimum feature size of the conductive features 94 is greater than the minimum feature size of the conductive features 74. In some cases, forming a back-side interconnect structure 90 having large conductive features 94 and high metal density can allow for reduced resistance and more efficient power distribution within the package component 100, in addition to thermal benefits.

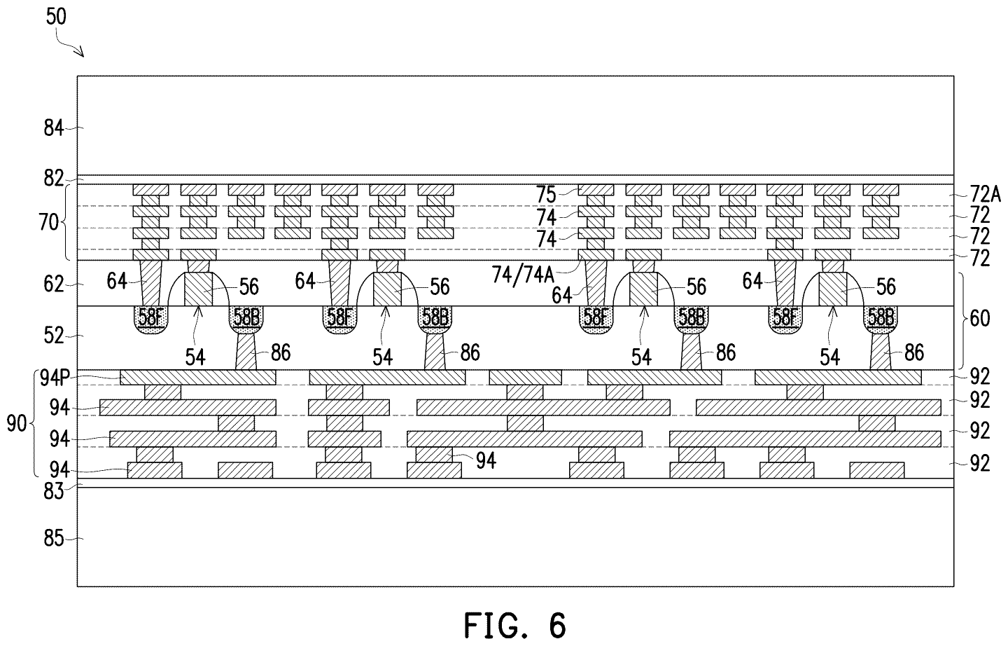

In FIG. 6, a second carrier substrate 85 is bonded to the back-side interconnect structure 90, in accordance with some embodiments. The second carrier substrate 85 may be similar to the first carrier substrate 84. For example, the second carrier substrate 85 may be a glass support substrate, a ceramic support substrate, a semiconductor substrate (e.g., a silicon substrate), a wafer (e.g., a silicon wafer), or the like. The second carrier substrate 85 may provide structural support during subsequent processing steps. The second carrier substrate 85 is substantially free of any active or passive devices. The second carrier substrate 85 may be bonded to the back-side interconnect structure 90 by one or more bonding layer(s) 83, which may be similar to the bonding layer(s) 82. For example, the second carrier substrate 85 may be bonded to the back-side interconnect structure 90 with dielectric bonding layer(s) 83 using dielectric-to-dielectric bonding, or the second carrier substrate 85 may be bonded to the back-side interconnect structure 90 with a bonding layer 83 that is a release layer or the like.

In FIG. 7, the first carrier substrate 84 and bonding layer(s) 82 are removed, in accordance with some embodiments. The first carrier substrate 84 and the bonding layer(s) 82 may be removed, for example, using an etching process, a CMP, a grinding process, a heating process, UV exposure, the like, or a combination thereof. The bond pads 75 and the bonding layer 72A of the front-side interconnect structure 70 are exposed after the bonding layer(s) 82 have been removed. In some embodiments, after removing the bonding layer(s) 82, surfaces of the bond pads 75 and the top-most dielectric layer 72 are substantially coplanar or level (within process variations).

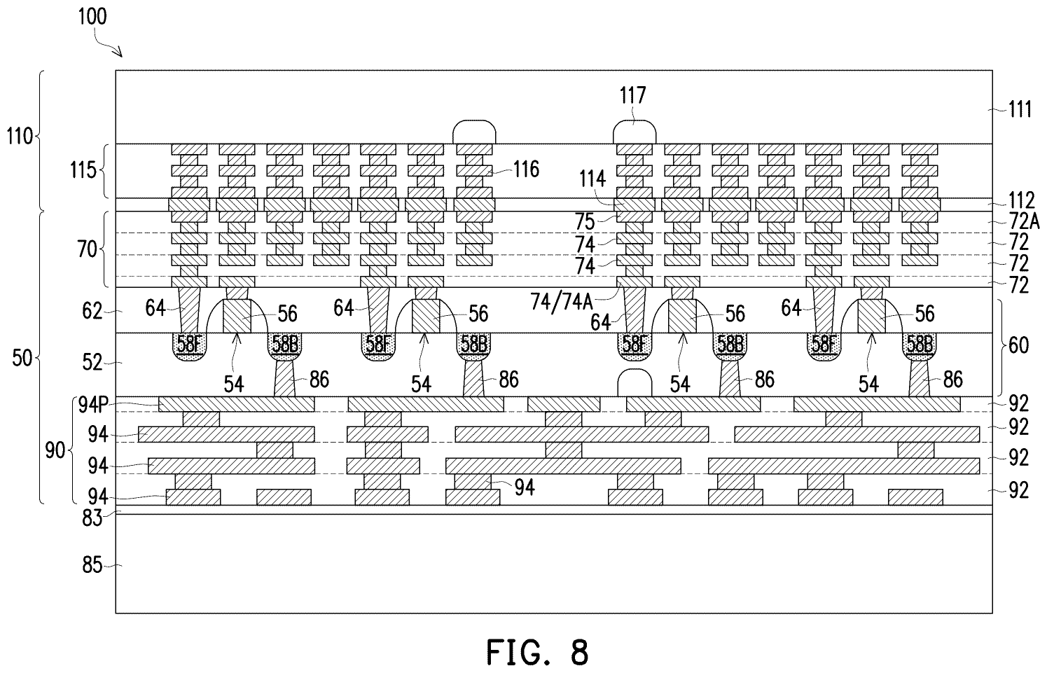

In FIG. 8, package die 110 is bonded to the integrated circuit die 50 to form a package component 100, in accordance with some embodiments. The package die 110 may be a semiconductor device, a chip, a die, a package, or the like. For example, the package die 110 may be a logic die (e.g., central processing unit (CPU), graphics processing unit (GPU), system-on-a-chip (SoC), application processor (AP), microcontroller, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. In some embodiments, the package die 110 may be a memory device such as a memory die (e.g., dynamic random access memory (DRAM) die, static random access memory (SRAM) die, etc.), a hybrid memory cube (HMC) module, a high bandwidth memory (HBM) module, or the like, which may include multiple memory dies.

In some embodiments, the package die 110 comprises a substrate 111, which may be similar to the semiconductor substrate 52 described previously or which may comprise other materials. For example, in some embodiments, the substrate 111 is a silicon substrate. In some embodiments, devices 117 may be formed in or on the substrate 111, which may be similar to the devices 54 described previously or may comprise other devices. The devices 117 may include passive and/or active devices. In some embodiments, an interconnect structure 115 is formed over and is electrically coupled to the devices 117. The interconnect structure 115 may be a redistribution structure or the like, and may comprise a plurality of conductive features 116 in a plurality of dielectric layers. In some cases, the interconnect structure 115 may be similar to the front-side interconnect structure 70, though other interconnect structures 115 are possible. In some cases, the interconnect structure 115 may be considered a Back-End-Of-Line (BEOL) metallization structure. In some embodiments, a bonding layer 112 is formed over the interconnect structure 115, and bond pads 114 are formed in the bonding layer 112. In some embodiments, the overall metal density of the back-side interconnect structure 90 may be higher than the overall metal density of the interconnect structure 115. For example, in some embodiments, the interconnect structure 115 has a metal density of less than about 50%, though other metal densities are possible.

The package die 110 may be bonded to the integrated circuit die 50 using dielectric-to-dielectric bonding and metal-to-metal bonding. For example, the bonding layer 112 of the package die 110 may be bonded to the bonding layer 72A of the front-side interconnect structure 70 using dielectric-to-dielectric bonding, and the bond pads 114 of the package die 110 may be bonded to the bond pads 75 of the front-side interconnect structure 70 using metal-to-metal bonding. In this manner, the package die 110 is physically and electrically connected to the integrated circuit die 50. In some embodiments, after bonding, the package die 110 may be thinned using a CMP, a grinding process, or the like.

The package die 110 may be attached to the integrated circuit die 50 by placing the package die 110 on the top bonding layer 72A and the bond pads 75, then bonding the package die 110 to the bonding layer 72A and the bond pads 75. The package die 110 may be placed by, e.g., a pick-and-place process. The bonding may include a pre-bonding and an annealing. During the pre-bonding, a small pressing force is applied to press the package die 110 (e.g., the bonding layer 112) against the integrated circuit die 50 (e.g., the bonding layer 72A). The pre-bonding is performed at a low temperature, such as about room temperature, and after the pre-bonding, the bonding layer 112 is bonded to the bonding layer 72A. The bonding strength is then improved in a subsequent annealing step, in which the bonding layer 112, the bond pads 114, the bonding layer 74A, and the bond pads 75 are annealed. After the annealing, direct dielectric-to-dielectric bonds such as fusion bonds are formed, bonding the bonding layer 112 to the bonding layer 72A. For example, the bonds may be covalent bonds between the material of the bonding layer 112 and the material of the bonding layer 72A. The bond pads 114 are connected to respective bond pads 75 with a one-to-one correspondence. The bond pads 114 and the bond pads 75 may be in physical contact after the pre-bonding, or may expand to be brought into physical contact during the annealing. Further, during the annealing, the material(s) of the bond pads 114 and the bond pads 75 (e.g., copper) intermingle, so that metal-to-metal bonds are also formed. Hence, the resulting bonds between the integrated circuit die 50 and the package die 110 include both dielectric-to-dielectric bonds and metal-to-metal bonds.

In FIG. 9, the second carrier substrate 85 and bonding layer(s) 83 are removed, and conductive connectors 98 are formed, in accordance with some embodiments. The second carrier substrate 85 and the bonding layer(s) 83 may be removed, for example, using an etching process, a CMP, a grinding process, a heating process, UV exposure, the like, or a combination thereof. Conductive features 94 of the back-side interconnect structure 90 are exposed after the bonding layer(s) 83 have been removed.

After removing the bonding layer(s) 83, a dielectric layer 96 is formed on the back-side interconnect structure 90. The dielectric layer 96 may be formed of one or more acceptable dielectric materials, such as photosensitive polymers, such as polyimide, polybenzoxazole (PBO), a benzocyclobutene (BCB) based polymer, combinations thereof, or the like. Other acceptable dielectric materials include silicon oxide, silicon nitride, low-k dielectrics such as carbon doped oxides, extremely low-k (ELK) dielectrics such as porous carbon doped silicon dioxide, combinations thereof, or the like. The dielectric layer 96 may be formed by spin coating, lamination, deposition (e.g., CVD), combinations thereof, or the like.

External connectors 97 may be formed in the dielectric layer 96 for external connection to the back-side interconnect structure 90, in accordance with some embodiments. The external connectors 97 are physically and electrically coupled to conductive features 94. The external connectors 97 may include conductive pillars, pads, or the like, to which external connections can be made. In some embodiments, the external connectors 97 may be under-bump metallizations (UBMs) or the like. The external connectors 97 may have bump portions on and extending along the major surface of the dielectric layer 96, and have via portions extending through the dielectric layer 96 to physically and electrically couple the conductive features 94. In some embodiments, openings are formed in the dielectric layer 96 that expose conductive features 94. The openings may be formed using suitable photolithography and/or etching techniques, for example. The conductive material of the external connectors 97 may then be deposited in the openings. The external connectors 97 can be formed of a conductive material such as a metal, such as copper, aluminum, titanium, multilayers thereof, combinations thereof, or the like, which can be formed by, for example, CVD, plating, or the like.

Conductive connectors 98 are formed on the external connectors 97. The conductive connectors 98 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 98 may include a conductive material such as solder, copper, aluminum, gold, nickel, silver, palladium, tin, the like, or a combination thereof. In some embodiments, the conductive connectors 98 are formed by initially forming a layer of solder through evaporation, electroplating, printing, solder transfer, ball placement, or the like. Once a layer of solder has been formed, a reflow may be performed in order to shape the material into the desired bump shapes. In another embodiment, the conductive connectors 98 include metal pillars (such as copper pillars) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. Other external connectors 97 and/or conductive connectors 98 are possible.

In this manner, a package component 100 may be formed of a package die 110 bonded to an integrated circuit die 50. In some embodiments, multiple package components 100 are formed on the same carrier substrate(s) and then singulated to form individual package components 100. Accordingly, sidewalls of the package die 110 and the integrated circuit die 50 may be substantially coplanar or coterminous, in some embodiments. In other embodiments, the package die 110 and the integrated circuit die 50 of a package component 100 may have different widths.

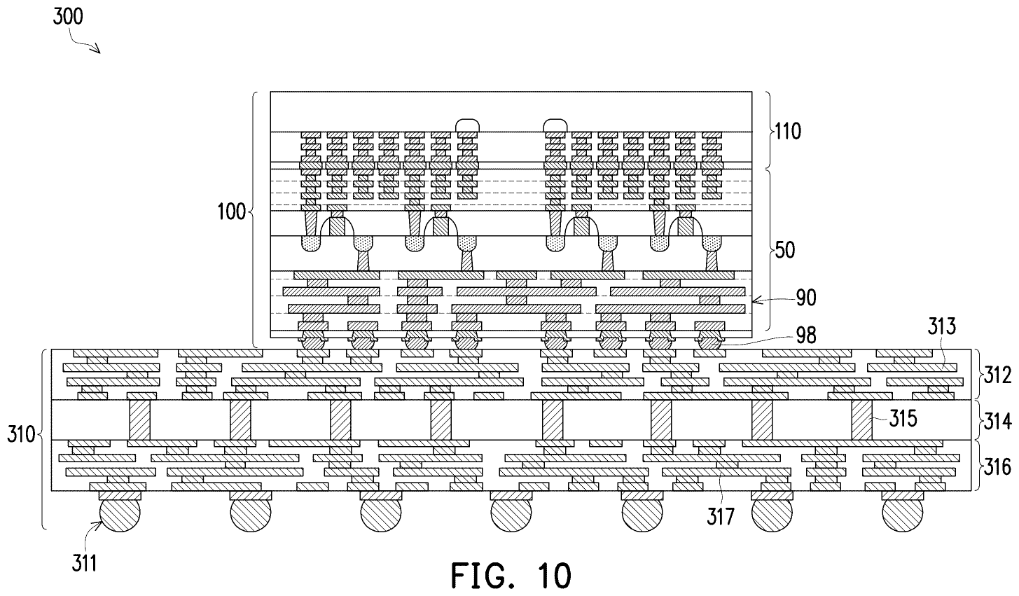

FIGS. 10-12 illustrate the bonding of a package component 100 to a package substrate 310 to form a package 300, in accordance with some embodiments. In FIG. 10, the package component 100 is bonded to the package substrate 310 using the conductive connectors 98 of the package component 100. The resulting package 300 may be a chip-on-wafer-on-substrate (CoWoS) package, although other types of packages may be formed.

In some embodiments, the package substrate 310 is a printed circuit board (PCB), an interposer, or the like. In some embodiments, the package substrate 310 includes a front-side redistribution structure 312 formed on a front side of a substrate core 314 and a back-side redistribution structure 316 formed on a back-side of the substrate core 314. The substrate core 314 may be formed of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may be used. Additionally, the substrate core 314 may be a silicon-on-insulator (SOI) substrate. Generally, an SOI substrate includes a layer of a semiconductor material such as epitaxial silicon, germanium, silicon germanium, or combinations thereof. The substrate core 314 is, in one alternative embodiment, based on an insulating core such as an organic core or a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto Build-Up Film (ABF) or other laminates may be used for the substrate core 314. In some embodiments, through vias 315 are formed in the substrate core 314 that electrically couple the front-side redistribution structure 312 and the back-side redistribution structure 316.

The front-side redistribution structure 312 comprises a plurality of conductive features 313, which may include conductive lines, conductive vias, bond pads, metallization patterns, redistribution layers, or the like. The conductive features 313 may be formed in a plurality of dielectric layers, in some embodiments. For example, the front-side redistribution structure 312 may be formed of alternating layers of dielectric material and layers of conductive material (e.g., copper) with vias interconnecting the layers of conductive material. The conductive features 313 may be formed using any suitable process (such as deposition, damascene, dual damascene, or the like). The dielectric material may be one or more materials similar to those described previously for the substrate core 314, the front-side interconnect structure 70, or the back-side interconnect structure 90.

In some embodiments, the conductive features 313 of the front-side redistribution structure 312 are large to facilitate heat transfer within the package 300. For example, larger conductive features 313 formed of metal may allow for the efficient transfer of heat away from the integrated circuit die 50. For example, in some embodiments, a thickness of a conductive feature 313 may be in the range of about 0.06 μm to about 0.6 μm, or a width of a conductive feature 313 may be in the range of about 0.12 μm to about 1.2 μm. Conductive features 313 may have other dimensions in other embodiments.

In some embodiments, the overall metal density of the front-side redistribution structure 312 may be high in order improve thermal spreading. For example, in some embodiments, conductive features 313 may form about 50% to about 70% of the volume of the front-side redistribution structure 312. Other metal densities are possible. In some embodiments, some conductive features 313 may be dummy conductive features that facilitate heat transfer. By forming a front-side redistribution structure 312 having large and dense conductive features 313, heat may be more efficiently transferred within a package 300. This can improve the thermal properties, the efficiency, the reliability, and the operation of the package 300.

The back-side redistribution structure 316 may be similar to the front-side redistribution structure 312, in some embodiments. For example, the back-side redistribution structure 316 may comprise a plurality of conductive features 317 formed in a plurality of dielectric layers, in some embodiments. The back-side redistribution structure 316 may have a total thickness that is less than, about the same as, or greater than the total thickness of the front-side redistribution structure 312. For example, in some embodiments, a thickness of a conductive feature 317 may be in the range of about 0.06 μm to about 0.6 μm, or a width of a conductive feature 317 may be in the range of about 0.12 μm to about 1.2 μm. Conductive features 317 may have other dimensions in other embodiments.

In some embodiments, the overall metal density of the back-side

redistribution structure 316 may be high in order improve thermal spreading. For example, in some embodiments, conductive features 317 may form about 50% to about 70% of the volume of the back-side redistribution structure 316. Other metal densities are possible. In some embodiments, some conductive features 317 may be dummy conductive features that facilitate heat transfer. By forming a back-side redistribution structure 316 having large and dense conductive features 317, heat may be more efficiently transferred within a package 300. This can improve the thermal properties, the efficiency, the reliability, and the operation of the package 300.

In some other embodiments, the dimensions of the conductive features 317 of the back-side redistribution structure 316 may be smaller than the dimensions of the conductive features 313 of the front-side redistribution structure 312. In some other embodiments, the overall metal density of the back-side redistribution structure 316 may be smaller than the overall metal density of the front-side redistribution structure 312. For example, in some embodiments, conductive features 317 may form less than about 50% of the volume of the back-side redistribution structure 316.

Connectors 311 may be formed on the back-side redistribution structure 316. The connectors 311 may be similar to the external connectors 97 and/or the conductive connectors 98 of the package component 100, in some embodiments. For example, the connectors 311 may comprise UBMs and solder bumps, or the like. Other connectors 311 are possible.

In some embodiments, the conductive connectors 98 of the package component 100 are placed on corresponding conductive features 313 (e.g. conductive pads, bond pads, or the like) of the front-side redistribution structure 312. A reflow process is performed to bond the package component 100 to the package substrate 310. In this manner, the package component 100 may be physically and electrically connected to the package substrate 310 In other embodiments, the package component 100 may be bonded to the package substrate 310 using dielectric-to-dielectric bonding and/or metal-to-metal bonding (e.g., direct bonding, fusion bonding, oxide-to-oxide bonding, hybrid bonding, or the like).

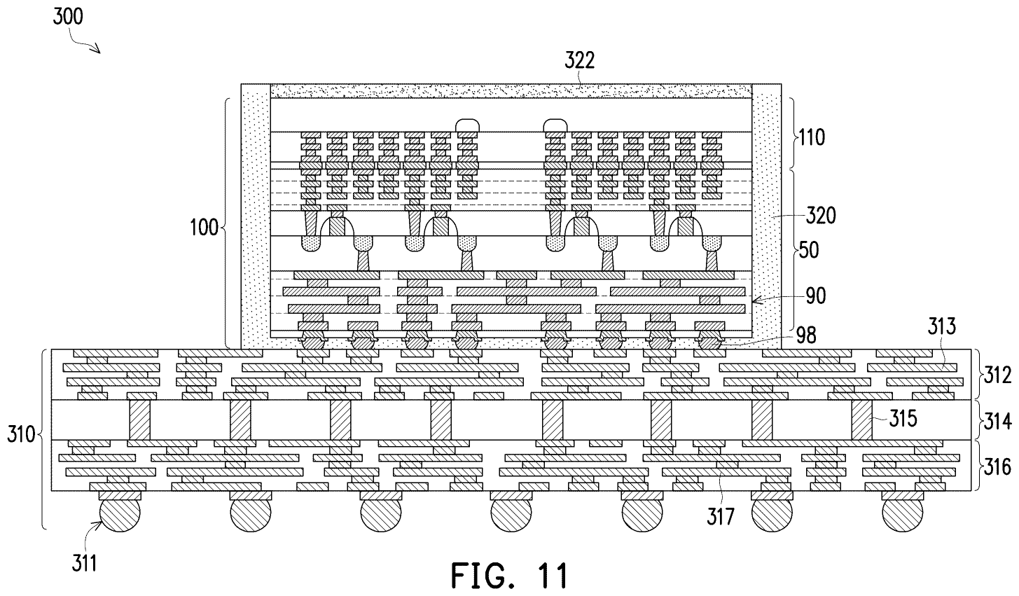

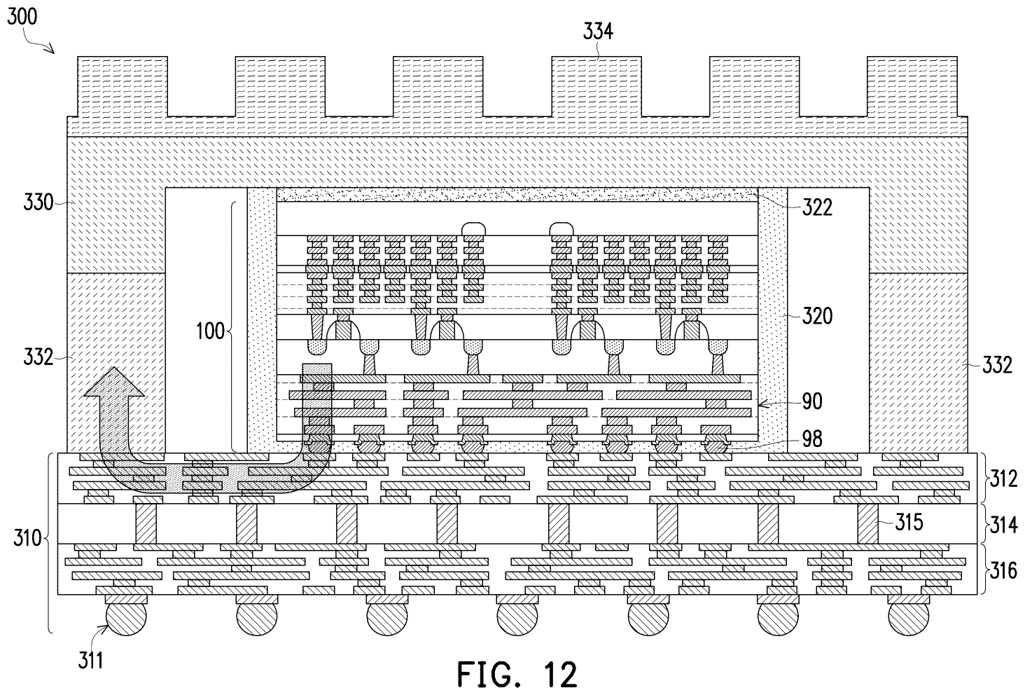

In FIG. 11, a thermal interface material (TIM) 322 is deposited on the package component 100, and a heat dissipation material 320 is deposited between the package component 100 and the package substrate 310, in accordance with some embodiments. The TIM 322 may facilitate heat transfer away from the package component 100 to an overlying feature such as a lid (e.g., lid 330 of FIG. 12). The heat dissipation material 320 may facilitate heat transfer away from the package component 100 to the package substrate 310. The TIM 322 may be deposited on the top surface of the package component 100, and may be a thermal paste, thermal adhesive, or the like.

The heat dissipation material 320 is deposited to fill the gap between the package component 100 and the package substrate 310. The heat dissipation material 320 may surround the conductive connectors 98. In this manner, the heat dissipation material 320 may be considered an underfill, in some cases. As shown in FIG. 11, the heat dissipation material 320 may also be deposited on sidewalls of the package component 100 and sidewalls of the TIM 322, in some embodiments. In this manner, the heat dissipation material 320 may surround the package component 100, in some embodiments. The heat dissipation material 320 may have a high thermal conductivity, and may be a “high-kappa” material. For example, in some embodiments, the heat dissipation material 320 may have a thermal conductivity greater than about 10 W/m·K. In some embodiments, the heat dissipation material 320 may have a thermal conductivity in the range of about 30 W/m·K to about 50 W/m·K, though other values are possible. In some embodiments, the heat dissipation material 320 may be cured after deposition. Using a high-kappa heat dissipation material 320 may allow for improved heat transfer from the package component 100 to the package substrate 310. The thermal dissipation benefits of a high-kappa heat dissipation material 320 may be combined with the thermal dissipation benefits of a high-metal-density back-side interconnect structure 90 and a high-metal-density front-side redistribution structure 312. In this manner, heat may be efficiently dissipated from the devices 54 of the package component 100, which can improve thermal stability and performance of the package component 100 and/or the package 300.

In some embodiments, the heat dissipation material 320 may be a composite material comprising a filler material dispersed in a base material. For example, the base material may be an epoxy, a resin, polyethylene, another polymer, or the like. In some embodiments, the base material may be a material having a thermal conductivity in the range of about 0.5 W/m·K to about 30 W/m·K, though other values are possible. The filler material may comprise particles of a thermally conductive (e.g., high-kappa) material, such as a material having a thermal conductivity in the range of about 1 W/m·K to about 100 W/m·K, though other values are possible. In some embodiments, the filler material comprises dielectric particles, such as silicon dioxide particles, titanium oxide particles, aluminum oxide particles, a combination thereof, or the like. In some embodiments, the filler material comprises metallic particles (e.g., metallic nanoparticles), such as gold nanoparticles, silver nanoparticles, a combination thereof, or the like. The metallic nanoparticles may have a diameter in the range of about 1 nm to about 10 nm, though other sizes of nanoparticles are possible. In some embodiments, the filler material comprises metallic nanotubes, such as gold nanoparticles, silver nanoparticles, a combination thereof, or the like. In some embodiments, the heat dissipation material 320 may comprise multiple types of filler material, such as a combination of dielectric particles, metallic particles, and/or metallic nanotubes. For example, in some embodiments, the heat dissipation material comprises a suitable combination of silicon dioxide particles, gold nanoparticles, gold nanotubes, silver nanoparticles, and/or silver nanotubes. Other filler materials or combinations of filler materials are possible. In some embodiments, the heat dissipation material 320 has a concentration of filler material in the range of about 50% by weight to about 90% by weight, though other concentrations are possible.

In FIG. 12, a lid 330 is attached to the structure to form a package 300, in accordance with some embodiments. The lid 330 may be formed of a thermally conductive material, such as a metal, to facilitate heat dissipation of the package 300. The lid 330 may be attached to the package substrate 310 using an adhesive 332 or the like. The adhesive 332 may be a thermally conductive material that facilitates heat transfer from the package substrate 310 to the lid 330. In some embodiments, the adhesive 332 may have a thickness in the range of about 20 μm to about 50 μm, though other thicknesses are possible. The lid 330 may also physically contact the TIM 322 and/or the heat dissipation material 320. In some embodiments, a cooling structure (e.g., a heat sink or the like) is attached to the lid 330 to further enhance heat dissipation of the package 300.

The package 300 described herein allows for improved transfer of heat from an integrated circuit die 50 through the back side of the package component 100. The improved back-side heat dissipation described herein may be useful, for example, for packages 300 in which the presence of the package die 110 reduces the heat transfer efficiency from the integrated circuit die 50 through the front side of the package component 100. The high-metal-density back-side interconnect structure 90 allows for efficient heat transfer away from the integrated circuit die 50 toward the back side of the package component 100. The high-kappa heat dissipation material 320 allows for efficient heat transfer from the back side of the package component 100 to the front-side redistribution structure 312. The high-metal-density front-side redistribution structure 312 then allows for efficient heat transfer away from the package component 100 and into the lid 330. In some embodiments, a high-metal-density back-side redistribution structure 316 may also further improve the transfer of heat away from the package component 100. An example back-side heat transfer path is shown by a large arrow in FIG. 12. In this manner, improved thermal performance of a package 300 may be achieved. Further, forming the integrated circuit die 50 near the back side of the package component 100 (e.g., under the package die 110) allows the integrated circuit die 50 to be electrically closer to the power supply, which is coupled to the integrated circuit die 50 through the package substrate 310. Forming the integrated circuit die 50 closer to the power supply can reduce resistive voltage drops and achieve improved performance and reduced energy consumption for the package 300.

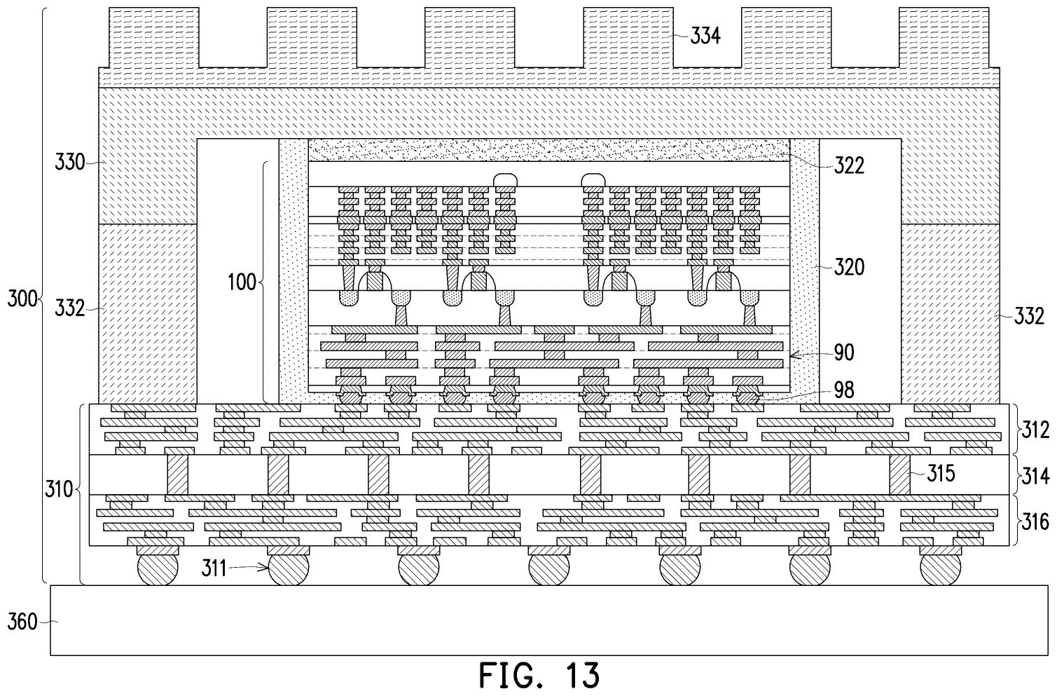

FIG. 13 illustrates the attachment of the package 300 to an external component 360, in accordance with some embodiments. The external component 360 may be any suitable electrical component, such as a device die, a redistribution structure, an interposer, a package substrate, a printed circuit board (PCB), a motherboard, or the like. The package 300 may be physically and electrically connected to the external component 360 using the connectors 311.

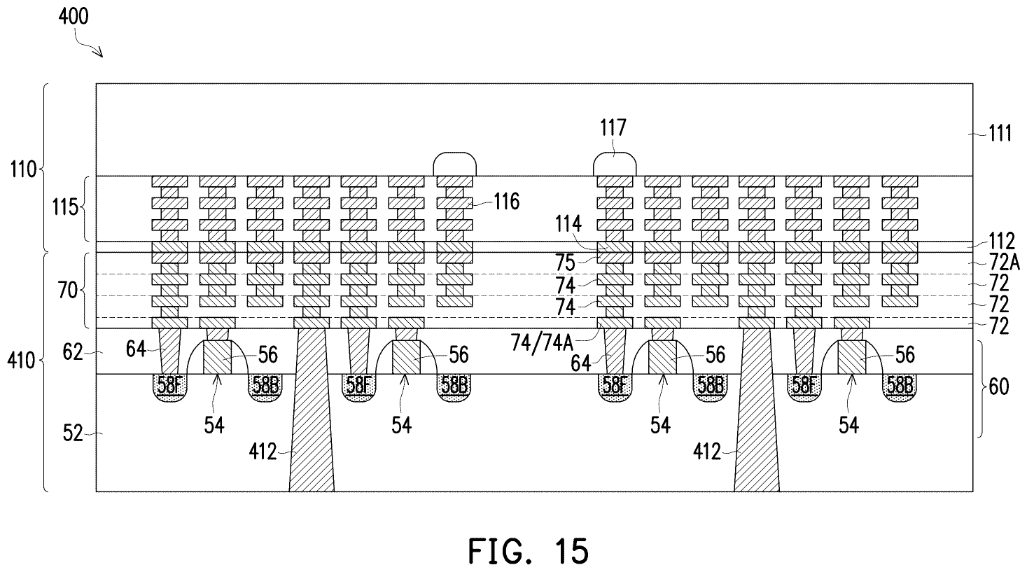

FIGS. 14-16 illustrate intermediate stages in the formation of a package component 400, in accordance with some embodiments. The package component 400 is similar to the package component 100 described previously for FIG. 9, except the integrated circuit die 410 of the package component 400 does not include a back-side interconnect structure 90. Instead of a back-side interconnect structure 90, the integrated circuit die 410 utilizes through vias 412 (see FIG. 15). In FIG. 14, a package die 110 is bonded to an integrated circuit structure 408. The package die 110 may be similar to the package die 110 described previously for FIG. 8. The integrated circuit structure 408 may be similar to the structure shown in FIG. 2. For example, the integrated circuit structure 408 includes devices 54 formed on a semiconductor substrate 52 and a front-side interconnect structure 70 formed over the devices 54. The package die 110 may be bonded to the front-side interconnect structure 70 using dielectric-to-dielectric bonding and metal-to-metal bonding, which may be similar to that described previously for FIG. 8.

In FIG. 15, through vias 412 are formed in the integrated circuit structure 408 to form an integrated circuit die 410, in accordance with some embodiments. In some embodiments, the semiconductor substrate 52 may be thinned before forming the through vias 412. For example, a CMP, grinding process, etching process, or the like may be applied to the back side of the semiconductor substrate 52 to thin the semiconductor substrate 52. Openings may be formed extending through the semiconductor substrate 52 and the inter-layer dielectric 62 to expose conductive features 74 of the front-side interconnect structure 70. The openings may be formed using acceptable photolithography and etching techniques. An optional liner, such as a diffusion barrier layer, an adhesion layer, or the like, and a conductive material are then formed in the openings. The optional liner may include titanium, titanium nitride, tantalum, tantalum nitride, a combination thereof, or the like. The liner may be deposited by a conformal deposition process, such as PVD, CVD, or the like. The conductive material may be tungsten, cobalt, ruthenium, aluminum, nickel, copper, a copper alloy, silver, gold, a combination thereof, or the like. The conductive material may be deposited by PVD, CVD, ALD, or the like. A planarization process, such as a CMP, may be performed to remove excess material from the back-side surface of the semiconductor substrate 52. The remaining liner and conductive material in the openings forms the through vias 412. In other embodiments, the through vias 412 may extend partially or fully through the front-side interconnect structure 70. For example, in other embodiments, the through vias 412 may protrude into the front-side interconnect structure 70 and contact conductive features 74 within. As another example, in other embodiments, the through vias 412 may extend through the front-side interconnect structure 70 to contact bond pads 75.

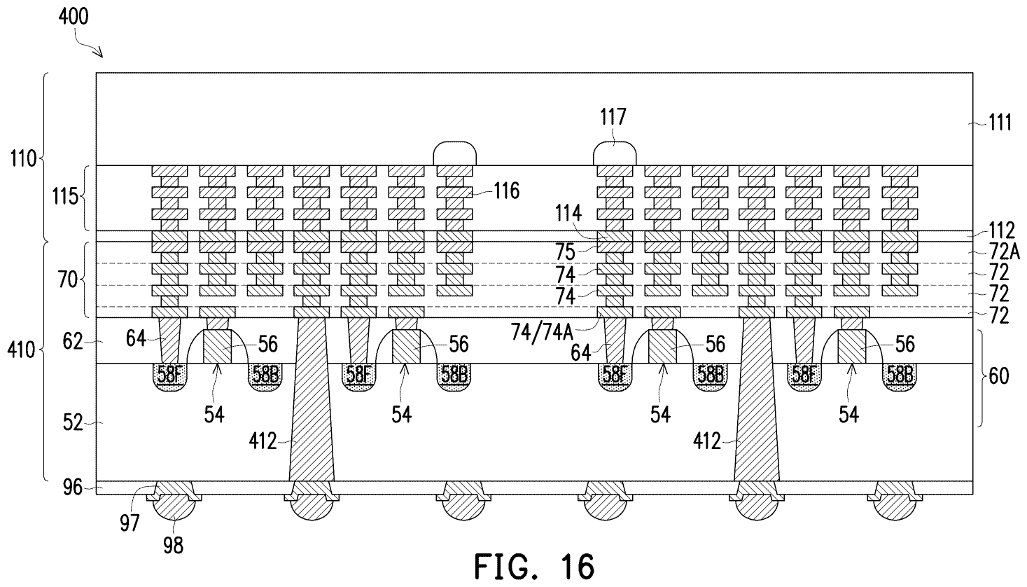

In FIG. 16, conductive connectors 98 are formed on the back side of the semiconductor substrate 52 to form a package component 400, in accordance with some embodiments. The conductive connectors 98 are electrically coupled to the through vias 412 and are thus electrically coupled to the front-side interconnect structure 70. The conductive connectors 98 may be similar to those described previously for FIG. 9, For example, a dielectric layer 96 may be formed over the back side of the semiconductor substrate 52 and patterned, external connectors 97 (e.g., UBMs or the like) may be formed in the dielectric layer 96, and conductive connectors 98 may then be formed on the external connectors 97.

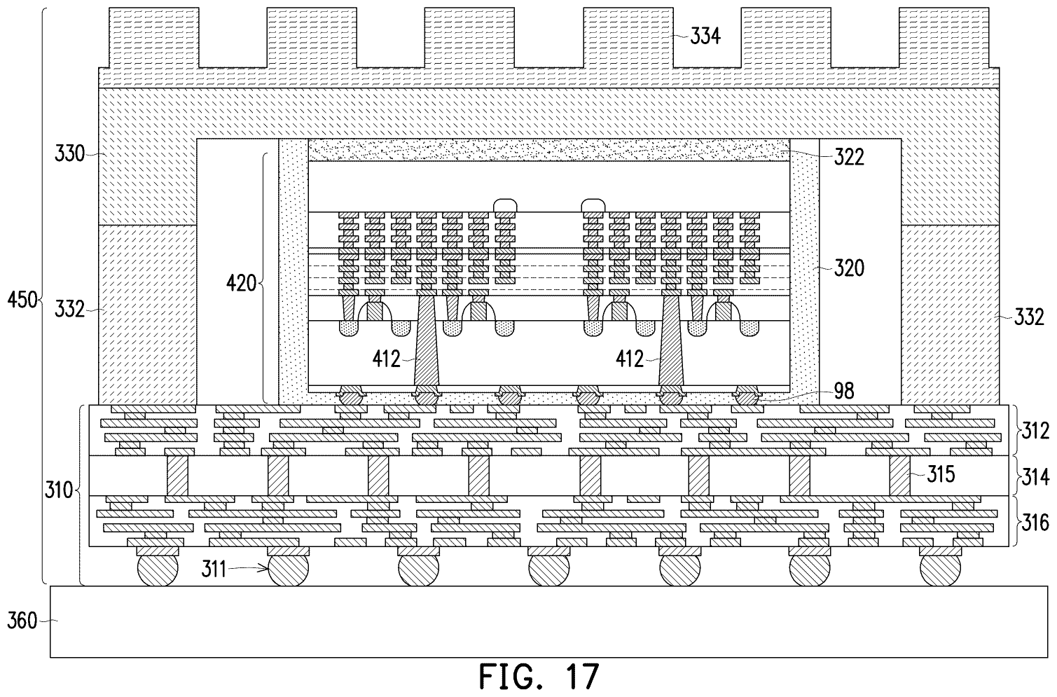

FIG. 17 illustrates the attachment of a package 450 to an external component 360, in accordance with some embodiments. The package 450 is similar to the package 300 of FIG. 12, except that a package component 420 is used instead of a package component 100. For example, the package component 420 may be bonded to a package substrate 310 using conductive connectors 98. The package substrate 310 may have a high-metal-density front-side redistribution structure 312, similar to the previously described package substrate 310. A high-kappa heat dissipation material 320 is deposited under and/or on sidewalls of the package component 420. The heat dissipation material 320 facilitates transfer of heat away from the back side of the package component 420 to the package substrate 310, and the front-side redistribution structure 312 of the package substrate 310 facilitates transfer of heat away from the package component 420. In this manner, thermal performance and reliability of a package 450 may be improved. The package 450 may be physically and electrically connected to the external component 360 using the connectors 311. The external component 360 may be similar to the external component 360 described previously for FIG. 13.

Other features and processes may also be included in the embodiments described herein. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments may achieve advantages. The embodiments described herein allow for the formation of a package component having a processing die located closer to a power supply while allowing for efficient heat transfer from the processing die. Locating a processing die closer to its power supply can reduce the effects of resistance and improve performance and efficiency. In some cases, the embodiments described herein allow for efficient thermal dissipation when a memory die (e.g., an SRAM or the like) is bonded to a bottom processing die (e.g., a CPU die or the like) in a face-to-face manner. Other dies are possible. Forming a package component having a high-metal-density interconnect structure, such as a metal density greater than about 50%, can allow for improved heat dissipation by the interconnect structure. Additionally, attaching the package component to a package substrate comprising high-metal-density redistribution structures can allow for improved heat dissipation by the redistribution structures. The use of a high-kappa heat dissipation material, such as a composite material having a high thermal conductivity, can further improve heat dissipation of a package structure. In this manner, the thermal performance of a package can be improved, which can improve the operation, reliability, and efficiency of the package. The techniques described herein can be used with existing package and cooling architectures, as well as existing form factors.

In accordance with some embodiments, a device includes a semiconductor die bonded to an integrated circuit die, wherein the integrated circuit die includes a first interconnect structure, wherein the first interconnect structure has a metal density of at least 50%; a first redistribution structure having a metal density of at least 50%, wherein the first interconnect structure is bonded to the first redistribution structure; and a composite heat dissipation material between a bottom surface of the first interconnect structure and a top surface of the first redistribution structure. In an embodiment, the composite heat dissipation material has a thermal conductivity in the range of 30 W/m·K to 50 W/m·K. In an embodiment, the semiconductor die is bonded to a second interconnect structure of the integrated circuit die, wherein the second interconnect structure has a metal density of less than 50%. In an embodiment, the composite heat dissipation material includes gold nanoparticles. In an embodiment, the composite heat dissipation material includes silicon oxide particles. In an embodiment, the semiconductor die is bonded to the integrated circuit die using dielectric-to-dielectric bonding. In an embodiment, the composite heat dissipation material covers sidewalls of the semiconductor die and the integrated circuit die. In an embodiment, the integrated circuit die is closer to the first redistribution structure than the semiconductor die.

In accordance with some embodiments, a package includes: a package component including: a first semiconductor die including: a front-side interconnect structure; and a back-side interconnect structure, wherein the back-side interconnect structure has a metal density greater than that of the front side interconnect structure; and a second semiconductor die bonded to the front-side interconnect structure; a package substrate including: a first redistribution structure, wherein the first redistribution structure has a metal density greater than that of the front side interconnect structure, wherein the package component is attached to the first redistribution structure; and an underfill between the package component and the package substrate, wherein the underfill has a thermal conductivity that is greater than 10 W/m·K. In an embodiment, the back-side interconnect structure includes a power supply line. In an embodiment, the back-side interconnect structure of the package component is bonded to the first redistribution structure. In an embodiment, the underfill includes a filler material in a base material, wherein the filler material includes at least one of metal nanoparticles or metal nanotubes, wherein the filler material is between 50% by weight and 90% by weight of the underfill. In an embodiment, the package substrate includes a second redistribution structure that has a metal density greater than that of the front side interconnect structure. In an embodiment, the back-side interconnect structure has a metal density in the range of 50% to 70%. In an embodiment, the package includes a lid that is attached to a top surface of the first redistribution structure and is attached to a top surface of the second semiconductor die.

In accordance with some embodiments, a method includes forming a first interconnect structure on a front side of a device layer; forming a second interconnect structure on a back side of the device layer, wherein the second interconnect structure has a metal density greater than 50%; attaching a semiconductor die to the first interconnect structure; attaching the second interconnect structure to a package substrate; depositing a high-kappa heat dissipation material between the second interconnect structure and the package substrate; and attaching a lid to the package substrate and the semiconductor die. In an embodiment, the package substrate includes a redistribution structure having a metal density greater than 50%. In an embodiment, the method includes depositing the high-kappa heat dissipation material on sidewalls of the semiconductor die. In an embodiment, the method includes forming through vias in a semiconductor substrate of the device layer, wherein the second interconnect structure is electrically coupled to devices of the device layer by the through vias. In an embodiment, the high-kappa heat dissipation material includes metal nanoparticles in an epoxy base material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. (canceled)

2. A method comprising:
bonding a first interconnect structure of a first semiconductor die to a second interconnect structure of a second semiconductor die using metal-to-metal bonding;
after bonding the first semiconductor die to the second semiconductor die, forming a through substrate via in the first semiconductor die that extends through a first substrate of the first semiconductor die to the first interconnect structure;
forming a conductive connector on the first substrate, wherein the conductive connector is connected to the through substrate via;
attaching the conductive connector to a redistribution structure of a package substrate; and
depositing a thermal underfill between the package substrate and the first semiconductor die, wherein the thermal underfill surrounds the conductive connector, wherein the thermal underfill has a thermal conductivity in the range of 30 W/m·K to 50 W/m·K.

3. The method of claim 2 further comprising depositing the thermal underfill on the second semiconductor die.

4. The method of claim 2 further comprising depositing a thermal interface material on the second semiconductor die.

5. The method of claim 2 further comprising attaching a lid to the package substrate, wherein the thermal underfill contacts an underside of the lid.

6. The method of claim 5, wherein the lid is attached to the package substrate by an adhesive, wherein the adhesive is free of the thermal underfill.

7. The method of claim 5, wherein the redistribution structure has a metal density that is greater than 50%.

8. The method of claim 2, wherein the thermal underfill comprises an epoxy.

9. The method of claim 2, wherein the conductive connector comprises solder.

10. A method comprising:
forming first die, comprising:
forming a front-side interconnect structure over a substrate;
thinning the substrate; and
forming a back-side interconnect structure over the thinned substrate, wherein the back-side interconnect structure has an overall metal density in the range of 50% to 70%;
bonding a second die to the front-side interconnect structure;
bonding the back-side interconnect structure to a redistribution structure of an interposer; and
depositing a heat dissipation material on the redistribution structure, on sidewalls of the first die, and on sidewalls of the second die.

11. The method of claim 10, wherein a top surface of the heat dissipation material is farther from the interposer than a top surface of the second die.

12. The method of claim 10, wherein the redistribution structure has an overall metal density in the range of 50% to 70%.

13. The method of claim 10, wherein the back-side interconnect structure has an overall metal density that is greater than an overall metal density of the front-side interconnect structure.

14. The method of claim 10, wherein after depositing the heat dissipation material, a top surface of the redistribution structure is free of the heat dissipation material.

15. The method of claim 10, wherein the heat dissipation material extends between the first die and the interposer.

16. A package comprising:
a first redistribution structure on a first substrate, wherein the first redistribution structure comprises a plurality of first conductive features in a plurality of first dielectric layers, wherein a total volume of the plurality of first conductive features is greater than a total volume of the plurality of first dielectric layers;
a plurality of solder bumps on the redistribution structure;
a first interconnect structure on the plurality of solder bumps, wherein the interconnect structure comprises a plurality of second conductive features in a plurality of second dielectric layers, wherein a total volume of the plurality of second conductive features is greater than a total volume of the plurality of second dielectric layers;
a second substrate on the first interconnect structure, wherein the second substrate comprises a plurality of active devices;
a second interconnect structure on the second substrate; and
a composite underfill material between the first redistribution structure and the first interconnect structure, wherein the composite underfill comprises a filler material comprising metal nanoparticles.

17. The package of claim 16, wherein the first interconnect structure comprises a power distribution network.

18. The package of claim 16 further comprising a second redistribution structure on the first substrate, wherein the second redistribution structure comprises a plurality of third conductive features in a plurality of third dielectric layers, wherein a total volume of the plurality of third conductive features is less than a total volume of the plurality of third dielectric layers

19. The package of claim 16, wherein the filler material further comprises metal nanotubes.

20. The package of claim 16, wherein the composite underfill material is between 50% and 90% filler material by weight.

21. The package of claim 16 further comprising a third interconnect structure on the second interconnect structure and a third substrate on the third interconnect structure.
